(19) United States
(12) Patent Application Publication
(10) Pub. No.: US 2014/0147999 A1
(43) Pub. Date: May 29, 2014

(54) METHOD OF FORMING GATE STRUCTURE

(71) Applicant: Shanghai Huali Microelectronics Corporation, Shanghai (CN)

(72) Inventor: Jun Zhou, Shanghai (CN)

(73) Assignee: Shanghai Huali Microelectronics Corporation, Shanghai (CN)

(21) Appl. No.: 14/081,686

(22) Filed: Nov. 15, 2013

(30) Foreign Application Priority Data
Nov. 28, 2012 (CN) 201210496608.9

(51) Int. Cl. H01L 21/28

(52) U.S. Cl. CPC H01L 21/28123; H01L 21/28035
USPC 438/585

(57) ABSTRACT

A method of forming a gate structure includes the steps of: providing a substrate; sequentially forming a polysilicon layer, a hard mask layer, an anti-reflection layer and a photoresist layer over the substrate; etching the hard mask layer using the anti-reflection layer and the photoresist layer as a mask; performing a SiCoNi process to trim the etched hard mask layer until the trimmed hard mask layer has a desired critical dimension; and etching the polysilicon layer to form a gate structure using the trimmed hard mask layer as a mask. The method is capable of precise control of the width and profile of the trimmed hard mask layer and can thereby result in a gate structure with a smaller critical dimension and an improved profile.

### CROSS-REFERENCES TO RELATED APPLICATIONS

This application claims the priority of Chinese patent application number 201210496608.9, filed on Nov. 28, 2012, the entire contents of which are incorporated herein by reference.

### TECHNICAL FIELD

The present invention relates generally to the semiconductor technology, and more particularly, to a method of forming a gate structure.

### BACKGROUND

In the semiconductor technology, an integrated circuit (IC) typically includes millions of electronic devices. With the development of technology and increasingly critical needs in practical applications, ICs have been required to be more compact, more multi-tier, flatter and thinner. For example, in a current modern very large scale integrated (VLSI) circuit, a silicon chip of only a few square millimeters generally includes tens of thousands to millions of transistors.

The requirements in miniaturization have brought great challenges to device fabrication processes. For instance, in the fabrications of circuits employing metal oxide semiconductor (MOS) transistors, how to form smaller and well-shaped polysilicon gates on a substrate so as to produce smaller transistors has been challenging the current semiconductor device fabrication processes.

In order to obtain a polysilicon gate having a certain critical dimension (CD), the conventional method is to trim a hard mask layer for the polysilicon gate into a size in accordance with the CD requirement, and then form the polysilicon gate by using the trimmed hard mask layer as an etching mask. However, because the process of trimming the hard mask layer cannot proceed completely linearly, when the trimming is required to be conducted for a long duration, it is hard to achieve precise CD control and the treated hard mask layer will have a poor profile, thus adversely affecting the subsequent process for etching the polysilicon gate.

More specifically, FIGS. 1 to 4 show a conventional method for forming a gate structure. Reference is first made to FIG. 1, which shows, in a first step of the method, a semiconductor substrate 10 is provided, on which a polysilicon layer 11, a hard mask layer 12, an anti-reflection layer 13 and a photoresist layer 14 are sequentially stacked in this order. Referring to FIG. 2, in a second step, the hard mask layer 12 is etched using the anti-reflection layer 13 and the photoresist layer 14 as an etching mask and thereafter trimmed using chlorine-containing plasma, thereby reducing the size of the hard mask layer 12 into a certain CD. In a third step, as shown in FIG. 3, the photoresist layer 14 and the anti-reflection layer 13 are removed, and the polysilicon layer 11 is etched into a polysilicon gate using the etched and trimmed hard mask layer 12 as a mask. Referring to FIG. 4, in a fourth step, the hard mask layer 12 is removed.

As indicated in FIG. 2, when the trimming of the hard mask layer 12 using the chlorine-containing plasma is performed for a long duration, it will disable the precise CD control for the hard mask layer 12 and thus be disadvantageous in forming a well-shaped polysilicon gate.

### SUMMARY OF THE INVENTION

It is accordingly an objective of the present invention to provide a gate structure formation method capable of precisely controlling the width and profile of the trimmed hard mask layer and thereby resulting in a gate structure with a smaller CD and an improved profile.

The foregoing objective is attained by a method of forming a gate structure, the method including:

providing a substrate;

sequantially forming a polysilicon layer, a hard mask layer, an anti-reflection layer and a photoresist layer over the substrate;

etching the hard mask layer using the anti-reflection layer and the photoresist layer as a mask;

performing a SiCoNi process to trim the etched hard mask layer until the trimmed hard mask layer has a desired critical dimension; and

etching the polysilicon layer to form a gate structure using the trimmed hard mask layer as a mask.

Optionally, the photoresist layer may have a thickness of 1000 Å to 4000 Å.

Optionally, the hard mask layer may be made of at least one of silicon oxide and silicon nitride.

Optionally, the hard mask layer may have a thickness of 200 Å to 4000 Å.

Optionally, the polysilicon layer may have a thickness of 400 Å to 1500 Å.

Optionally, the SiCoNi process may be a multi-cycle low etching rate process with each cycle using ammonia and nitrogen fluoride as reaction gases to trim the hard mask layer by a width of 10 Å to 30 Å.

Optionally, a flow rate of ammonia may be 80 sccm to 160 sccm and a flow rate of nitrogen fluoride may be 1 sccm to 10 sccm.

Optionally, each cycle of the SiCoNi process may be followed by an annealing process.

Optionally, the annealing process may be performed at a temperature of 180° C.

From the above description, it can be understood that the method of this invention has the advantages as follows:

As the SiCoNi process has a high etching selectivity ratio of silicon to silicon oxide and/or silicon nitride, trimming the hard mask layer using the SiCoNi process enables precise control of the width and profile of the trimmed hard mask layer and can thereby result in a gate structure with a smaller CD and improved profile.

### BRIEF DESCRIPTION OF THE DRAWINGS

FIGS. 1 to 4 are cross-sectional views schematically illustrating a method of the prior art for forming a gate structure.

FIG. 5 is a flowchart graphically illustrating a method of forming a gate structure in accordance with one specific embodiment of the present invention.

FIGS. 6 to 9 are cross-sectional views schematically illustrating a method of forming a gate structure in accordance with one specific embodiment of the present invention.

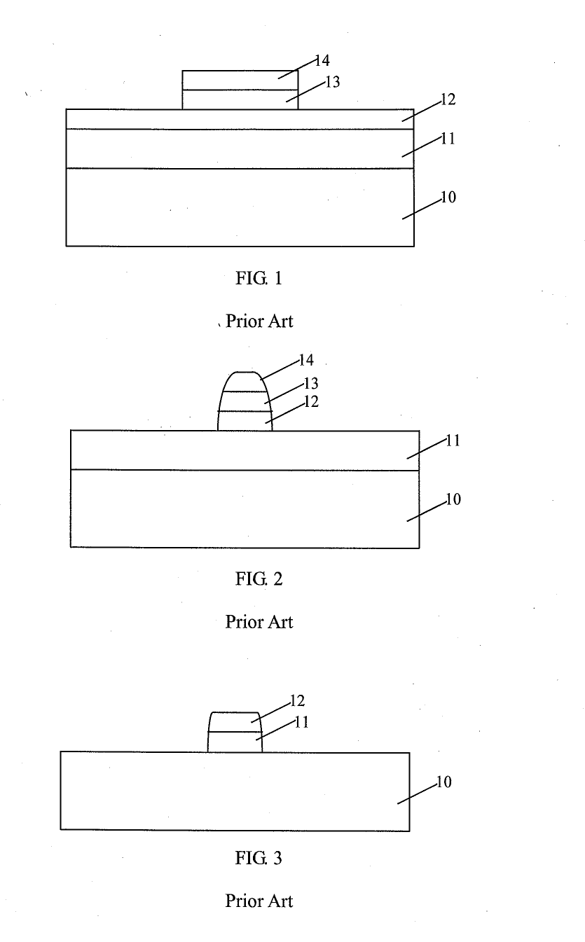

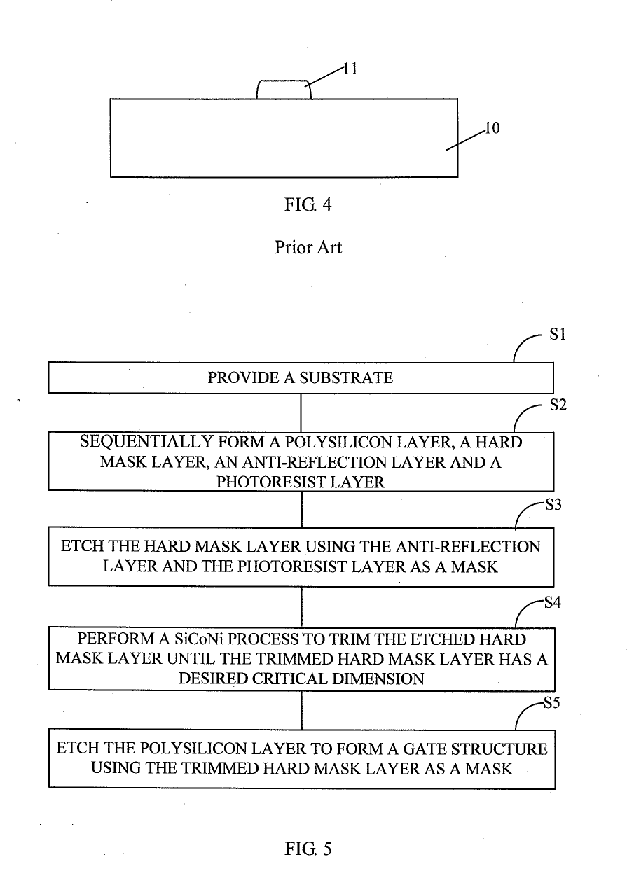

### DETAILED DESCRIPTION

The present invention provides a gate structure formation method capable of better controlling the width and profile, and precisely controlling a critical dimension (CD), of a trimmed hard mask layer and thereby resulting in a gate structure with a precisely controlled CD and a satisfactory profile. As shown in FIG. 5, in some embodiments of the invention, the method includes the steps of

step S1, providing a substrate;

step S2, sequantially forming a polysilicon layer, a hard mask layer, an anti-reflection layer and a photoresist layer over the substrate;

step S3, etching the hard mask layer using the anti-reflection layer and the photoresist layer as a mask;

step S4, performing a SiCoNi process to trim the etched hard mask layer until the trimmed hard mask layer has a desired CD; and

step S5, etching the polysilicon layer to form a gate structure using the trimmed hard mask layer as a mask.

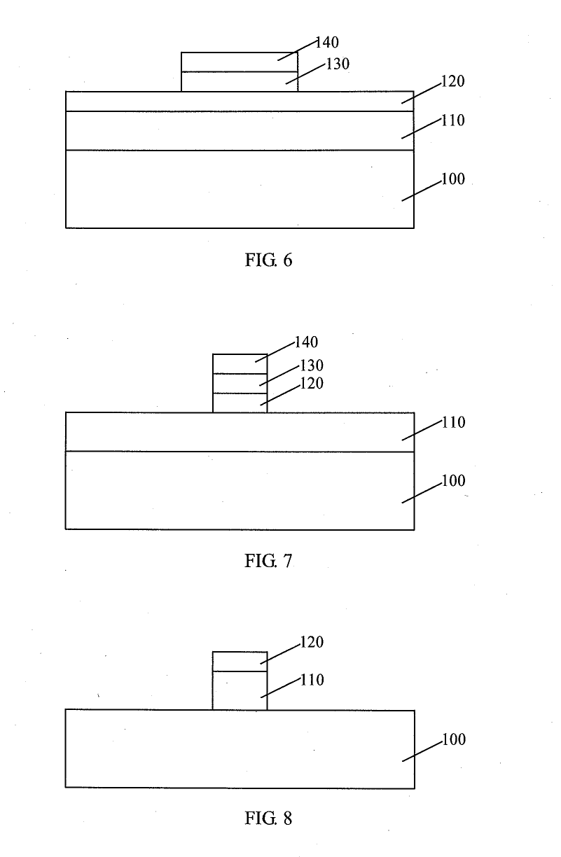

The invention is described in further detail hereinafter with reference to one specific embodiment, taken in conjunction with FIGS. 6 to 9, which are cross-sectional views schematically illustrating a method of forming a gate structure in accordance with the specific embodiment.

Now, referring to FIG. 6, the method first provides a substrate 100 having a polysilicon layer 110, a hard mask layer 120, an anti-reflection layer 130 and a photoresist layer 140 formed thereon. The substrate 100 may be a silicon substrate. The polysilicon layer 110 may have a thickness of 400 Å to 1500 Å, such as, for example, 400 Å, 800 Å, 1100 Å, 1500 Å, etc. The anti-reflection layer 130 may have a thickness of 200 Å to 1000 Å. The photoresist layer 140 may have a thickness of 1000 Å to 4000 Å and be formed of 193-nm photoresist. Both the photoresist layer 140 and the anti-reflection layer 130 are patterned using known semiconductor manufacturing processes. The hard mask layer 120 may be comprised of at least one of silicon oxide and silicon nitride. In one embodiment, the hard mask layer 120 is a silicon oxide layer. The hard mask layer 120 may have a thickness of 200 Å to 4000 Å.

Next, with reference to FIG. 7, the hard mask layer 120 is etched using the anti-reflection layer 130 and the photoresist layer 140 as a mask. After that, a SiCoNi process is further performed to trim the etched hard mask layer 120 until the trimmed hard mask layer 120 has a desired CD. Advantageously, the SiCoNi process, as a weak etching process with high precision, has a high etching selectivity ratio of silicon to silicon oxide and/or silicon nitride, and is thus capable of precise etching control, which is beneficial for the control of the profile and size of the trimmed hard mask layer 120. In this embodiment, the SiCoNi process is a multi-cycle low etching rate process. In each cycle of the SiCoNi process, ammonia (NH₃) and nitrogen fluoride (NF₃) are used as reaction gases to trim the hard mask layer by a width of 10 Å to 30 Å, namely a reduction in width of 10 Å to 30 Å, followed by an annealing process, wherein a flow rate of ammonia is 80 sccm to 160 sccm and a flow rate of nitrogen fluoride is 1 sccm to 10 sccm; the annealing process is performed at a temperature of 180° C. The cycles are repeated until the trimmed hard mask layer reaches a desired critical dimension.

After the SiCoNi process, referring to FIG. 8, the remaining anti-reflection layer 130 and photoresist layer 140 on the hard mask layer 120 are removed, and the underlying polysilicon layer 110 is etched to form a gate structure using the trimmed hard mask layer 120 as a mask.

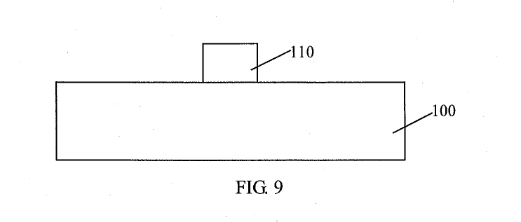

At last, as shown in FIG. 9, the hard mask layer 120 is removed.

As indicated in the foregoing description, as the SiCoNi process has a high etching selectivity ratio of silicon to silicon oxide and/or silicon nitride, trimming the hard mask layer using the process enables precise control of the width and profile of the trimmed hard mask layer and can thereby result in a gate structure with a smaller CD and an improved profile.

Those skilled in the art will realize that the above described preferred embodiments are intended only to illustrate the principles and features of the present invention and teach one or more ways of practicing or implementing the invention, not to restrict its scope in any way. Accordingly, all equivalent changes and modifications made in light of the above teachings will be considered to be within the scope of the invention.

What is claimed is:

1. A method of forming a gate structure, comprising:
providing a substrate;
sequantially forming a polysilicon layer, a hard mask layer, an anti-reflection layer and a photoresist layer over the substrate;
etching the hard mask layer using the anti-reflection layer and the photoresist layer as a mask;
performing a SiCoNi process to trim the etched hard mask layer until the trimmed hard mask layer has a desired critical dimension; and
etching the polysilicon layer to form a gate structure using the trimmed hard mask layer as a mask.

2. The method of claim 1, wherein the photoresist layer has a thickness of 1000 Å to 4000 Å.

3. The method of claim 1, wherein the hard mask layer is made of at least one of silicon oxide and silicon nitride.

4. The method of claim 1, wherein the hard mask layer has a thickness of 200 Å to 4000 Å.

5. The method of claim 1, wherein the polysilicon layer has a thickness of 400 Å to 1500 Å.

6. The method of claim 1, wherein the SiCoNi process is a multi-cycle low etching rate process with each cycle using ammonia and nitrogen fluoride as reaction gases to trim the hard mask layer by a width of 10 Å to 30 Å.

7. The method of claim 6, wherein a flow rate of ammonia is 80 sccm to 160 sccm and a flow rate of nitrogen fluoride is 1 sccm to 10 sccm.

8. The method of claim 6, wherein each cycle of the SiCoNi process is followed by an annealing process.

9. The method of claim 8, wherein the annealing process is performed at a temperature of 180° C.
